(19) United States
(12) Patent Application Publication
(10) Pub. No.: US 2025/0201674 A1
(43) Pub. Date: Jun. 19, 2025

(54) Engineered Interconnect Structures for Enhanced Bonding Strength

(71) Applicant: Wolfspeed, Inc., Durham, NC (US)

(72) Inventors: Brice McPherson, Springdale, AR (US); Brandon Robert Scaggs, Farmington, AR (US); Aryn Makenzie Hays, Springdale, AR (US); Peter Joseph Sakakini, Fayetteville, AR (US); Brandon Scott Passmore, Fayetteville, AR (US)

(21) Appl. No.: 18/541,571

(22) Filed: Dec. 15, 2023

(51) Int. Cl. H01L 23/495; H01L 23/00

(52) U.S. Cl. CPC H01L 23/49541; H01L 24/37; H01L 24/40; H01L 24/45; H01L 24/48; H01L 2224/37005; H01L 2224/40245; H01L 2224/45005; H01L 2224/48245

(57) ABSTRACT

Interconnect structures for power semiconductor device packages are provided. In one example, a power semiconductor device package may include one or more semiconductor die, a submount, and at least one interconnect structure. The one or more wide bandgap semiconductor die may be on the submount. The at least one interconnect structure may include at least one texturized surface.

### FIELD

The present disclosure relates generally to semiconductor device packages.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. Interconnect structures (e.g., wire bond structures, ribbon bond structures, clip structures, etc.) may be used to electrically connect structures in semiconductor device packages.

### SUMMARY

Aspects and advantages of embodiments of the present disclosure will be set forth in part in the following description, or may be learned from the description, or may be learned through practice of the embodiments.

One example aspect of the present disclosure is directed to a power semiconductor device package. The power semiconductor device package includes one or more semiconductor die. The power semiconductor device package includes a submount. The one or more semiconductor die are on the submount. The power semiconductor device package includes at least one interconnect structure. The at least one interconnect structure includes at least one texturized surface.

Another example aspect of the present disclosure is directed to a method. The method includes providing an interconnect structure for a power semiconductor device package. The method includes processing at least one surface of the interconnect structure using a texturizing process to provide at least one texturized surface on the interconnect structure.

Another example aspect of the present disclosure is directed to an interconnect structure for a power semiconductor device package. The interconnect structure includes a conductive structure. The interconnect structure includes at least one texturized surface on the conductive structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example power semiconductor device package according to example embodiments of the present disclosure.

FIG. 2 depicts example texturized surfaces of an interconnect structure according to example embodiments of the present disclosure.

FIG. 3 depicts example texturized surfaces of an interconnect structure according to example embodiments of the present disclosure.

FIG. 4 depicts example texturized surfaces of an interconnect structure according to example embodiments of the present disclosure.

FIG. 5 depicts example texturized patterns according to example embodiments of the present disclosure.

FIG. 6 depicts an example surface texturization process according to example embodiments of the present disclosure.

FIG. 7 depicts an example surface texturization process according to example embodiments of the present disclosure.

FIG. 8 depicts an example surface texturization process for interconnect structures according to example embodiments of the present disclosure.

FIG. 9 depicts an example surface texturization process for interconnect structures according to example embodiments of the present disclosure.

FIG. 10 depicts an example surface texturization process for interconnect structures according to example embodiments of the present disclosure.

FIG. 11 depicts an example surface texturization process for interconnect structures according to example embodiments of the present disclosure.

FIG. 12 depicts an example surface texturization process for interconnect structures according to example embodiments of the present disclosure.

FIG. 13 depicts an example surface texturization process for interconnect structures according to example embodiments of the present disclosure.

FIG. 14 depicts an example surface texturization process for interconnect structures according to example embodiments of the present disclosure.

FIG. 15 depicts an example surface texturization process for interconnect structures according to example embodiments of the present disclosure.

FIG. 16 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to semiconductor device packages (e.g., discrete semiconductor device packages and power modules) for use in semiconductor applications and other electronic applications. In some embodiments, semiconductor device packages may include one or more semiconductor dies having at least one semiconductor device. For instance, the semiconductor die may include, for instance, wide bandgap semiconductor devices, such as silicon carbide-based semiconductor devices (e.g., MOSFETs, Schottky diodes), Group III nitride-based semiconductor devices (e.g., high electron mobility transistor (HEMT) devices), etc. The semiconductor die may include a substrate, such as a wide bandgap substrate, such as a silicon carbide substrate. The semiconductor die may include an epitaxial layer on the substrate, such as a wide bandgap epitaxial layer, such as silicon carbide epitaxial layer and/or a Group III-nitride epitaxial layer.

Aspects of the present disclosure are discussed with reference to wide bandgap semiconductors for purposes of illustration and discussion. Aspects of the present disclosure may be implemented for semiconductor device packaging using other materials, such as silicon based semiconductor devices (e.g., IGBTs).

Example aspects of the present disclosure are directed to attaching semiconductor die (e.g., wide bandgap semiconductor die) to components within a semiconductor device package (e.g., a power module or discrete semiconductor package), or other structures, through different bonding processes (e.g., wire bonding processes). During different bonding processes, maintaining the integrity of the devices within the bonding process may be important to reduce failure of components and wasted materials. Maintaining the integrity of devices within bonding processes is becoming increasingly important as power semiconductor devices have increasingly smaller features that handle higher currents and require more energy to manufacture.

In some semiconductor device packages, one or more semiconductor die may be attached to a plurality of components using one or more interconnect structures (e.g., ribbon structures, clip structures, wire structures, lead frames, etc.). As used herein, an interconnect structure is any structure including a conductive structure, or made of a conductive material, and used to attach one component, such as a semiconductor die, to another component, such as a submount. For example, a semiconductor die may be attached to a lead frame using a wire structure. The wire structure may be subjected to a bonding process (e.g., ultrasonic or thermal bonding process) to secure the interconnect structure to the submount and the semiconductor die. As used herein, the term “bonding” or “bonding process” refers to causing a transition of a material from a first form to a second form. A bonding process may or may not require attaching a component to the material. Sintering, reflow, annealing, curing, exposing to light, exposing to ultraviolet light, and ultrasonic bonding are examples of bonding processes and are encompassed by the term “bonding” or “bonding process” in the disclosure and in the claims.

The various bonding processes used in the semiconductor industry present specific challenges and limitations. For instance, ultrasonic and thermal bonding processes for attaching interconnect structures (e.g., wire bond structures) to semiconductor die may adversely affect the integrity, performance, and reliability of the semiconductor die. Some bonding processes, such as ultrasonic bonding processes, are intense high-energy events that may create anomalies and/or failures within a semiconductor device package. The anomalies and/or failures may manifest as cracking, cratering, chipping, or other damage to the various components of the semiconductor device package. The anomalies and/or failures may, in turn, affect the electrical, mechanical, and thermal properties of the resulting semiconductor device package. For example, if an ultrasonic bonding process takes too long to apply sufficient energy to create an ultrasonic bond, the excess vibrations may damage the semiconductor device package, such as to the one or more semiconductor dies within the semiconductor device package.

Materials used within interconnect structures of the semiconductor industry may present additional challenges and limitations. For instance, the materials commonly used within interconnect structures may be conductive metals, such as gold and aluminum and relatively harder conductive metals, such as copper and aluminum alloys Hard conductive metals may require substantial energy to effectively thermal or ultrasonic bond them to a semiconductor die. The substantial energy required may increase the likelihood of anomalies and/or failures within the semiconductor die.

In addition, as semiconductor devices are designed to handle larger amounts of energy, the semiconductor devices may require larger interconnect structures. As the interconnect structures increase in size, the energy required to effectively bond them increases. The increased energy may increase the likelihood of failures and/or anomalies to occur within semiconductor devices.

Accordingly, example aspects of the present disclosure are directed to interconnect structures with texturized surfaces, and methods of manufacturing the same. As used herein, a texturized surface refers to a surface that has undergone a process to impart physical surface modification. The modification may include, but is not limited to, changes in surface roughness or surface pattern. The texturized surface can be achieved through various processes, such as roughening, etching, embossing, laser ablation, chemical treatments, or other processes.

Texturizing the surface(s) of interconnect structures may reduce the energy required in bonding processes between interconnect structures and other components, such as semiconductor die. In some embodiments, texturizing the surface of an interconnect structure may increase the frictional interlocking between the interconnect structure and another component, such as a bonding pad of a semiconductor die or a submount (e.g., a lead frame), during a bonding process (e.g., ultrasonic or thermal bonding process). The greater the frictional interlocking between components, the less overall energy required during a bonding process to create an effective and robust bond. In some embodiments, texturizing the surface of an interconnect structure may increase the surface area of the interconnect structure that may be utilized in a bonding process. The greater the surface area available in a bonding process, the greater the amount of frictional interlocking that may be achieved during the bonding process.

In some embodiments, the surface of an interconnect structure may be texturized on different areas of the surface of the interconnect structure. For instance, the interconnect structure may be a multi sided structure and may include a texturized surface on one side of the interconnect structure. In some embodiments, the interconnect structure may include a texturized surface in an isolated or localized area of the surface the interconnect structure. For example, only the end (e.g., tip) of the interconnect structure may include a texturized surface. In some embodiments, all surfaces, and/or the entire surface, of the interconnect structure may include a texturized surface.

In some embodiments, the surface of an interconnect structure may be texturized in engineered geometries. In some embodiments, the surface of an interconnect structure may be texturized in a randomized roughness. For instance, the surface of an interconnect structure may be texturized in a regular and flat pattern. The texturization of the surface of the interconnect structure may follow a relatively shallow patterned geometry and array and may include a set depth along a plane parallel to the surface of the interconnect structure. In some embodiments, the surface of an interconnect structure may be texturized in a regular and profiled pattern. The texturization of the surface of the interconnect structure may follow a relatively shallow patterned geometry and array and may include a contoured depth along a plane parallel to the surface of the interconnect structure. In some embodiments, the surface of an interconnect structure may be texturized in an anchor pattern. In some embodiments, the surface of the interconnect structure may be texturized in an irregular pattern. The texturization of the surface of the interconnect structure may include a random variation of roughness defined by a surface roughness. The surface roughness Ra (arithmetic average roughness) of the texturized surface of the interconnect structure may be in a range between about 5 microns to about 100 microns, such as in a range of about 5 microns to about 50 microns for shallow textures, such as about 51 microns to about 100 microns for deeper textures.

In some embodiments, the surface of an interconnect structure may be texturized with a texturized pattern. The texturized pattern may be a repeated pattern across at least a portion of the texturized surface of the interconnect structure. The texturized pattern may be a variety of different patterns. For instance, the texturized pattern may be a parallel line pattern, an orthogonal line pattern, a wave line pattern, a zig-zag line pattern, a grid line pattern, a crosshatch line pattern, a polygonal line pattern, a linear array of polygons pattern, a staggered array polygons pattern, or other two-dimensional pattern. It should be appreciated that the patterns provided are for example purposes only. In practice, any pattern may be used to texturize the surface of an interconnect structure; the patterns provided herein are used for example purposes only.

Example aspects of the present disclosure are directed to a plurality of different methods for texturizing the surface of interconnect structures. It should be appreciated that the methods detailed herein are described in a high-level form. For example, a reel-to-reel process may have many additional features, such as spoolers, de-spoolers, tensioners, and the like. For the purposes of the present disclosure, a reel-to-reel spooling process includes one reel spooling onto another reel. Similarly, some of the processes may be procedural, such as multiple methods or processes in line with one another, or multiple aspects of different methods in line with one another, such as rollers with different textures used to form a composite crosshatch line pattern.

In some embodiments, texturizing the surface of an interconnect structure may be accomplished by a standalone process, such as a reel-to-reel process. The interconnect structure may be texturized and stored and/or used in a plurality of different processes, such as different bonding processes (e.g., ultrasonic bonding processes or thermal bonding processes), at a later point. In some embodiments, the surface of an interconnect structure may be texturized in line with a plurality of different processes. As used herein, “in line” may refer to being within the process flow in one or more machines for attaching interconnect structures to semiconductor components. For example, the surface of the interconnect structure may be texturized directly before being used in a bonding process (e.g., ultrasonic bonding process) on a manufacturing line or as part of a fabrication process.

In some embodiments, the surface of an interconnect structure may be texturized using one or more rollers. For instance, an interconnect structure may be moved between one or more rollers that may texturize a surface of the interconnect structure. The rollers may include a texturized pattern that may be applied to the interconnect structure as it is passed between the one or more rollers. In some embodiments, there may be one roller that only texturizes one side of the interconnect structure. In some embodiments, there may be multiple rollers that texturize the surface of multiple sides of the interconnect structure. In some embodiments, the one or more rollers may be an abrasive wheel that roughens the surface of the interconnect structure in a randomized, uniform roughness.

In some embodiments, the surface of an interconnect structure may be texturized using one or more lasers. The one or more lasers may include a laser ablation system that may optically roughen the surface of the interconnect structure. The one or more lasers may apply any arbitrary or any defined pattern all over, or selectively on one or all sides of, the surface of the interconnect structure. Lasers may provide reduced wear and maintenance in comparison to other methods disclosed herein. The one or more lasers may be arranged on multiple sides of the material or may be in-line for a procedural operation.

In some embodiments, the surface of an interconnect structure may be texturized using one or more spraying nozzles. The one or more spraying nozzles may be used to apply an abrasive spray to the surface of the interconnect structure. The abrasive spray may remove material from the surface of the interconnect structure to create a general roughness of the surface of the interconnect structure or texturized pattern on the surface of the interconnect structure. In some embodiments, the one or more spraying nozzles may be used to apply a chemical etchant to the surface of the interconnect structure. A chemical etchant may partially etch the surface of the interconnect structure, creating an irregular rough surface. In some examples, an etchant or abrasive spray process may include cleaning, surface preparation, neutralizing, washing, drying, and other chemical processes. In addition, there may be additional sprays and/or baths to accomplish the texturizing process.

In some embodiments, the surface of an interconnect structure may be texturized using a fluid bath. The interconnect structure may go through an etchant bath that may texturize the surface of the interconnect structure. In some embodiments, the interconnect structure may be fed through an electrolyte bath. The interconnect structure may be texturized through an electrolysis process. Specifically, the interconnect structure may have a current applied and may act as an anode within the electrolyte bath. The electrolyte bath may include grounded plates that may act as a cathode, and the interconnect structure may pass near or between the grounded cathode plates. Based on the voltage difference between the interconnect structure (e.g., anode) and cathode plates, atoms of the surface of the interconnect structure may dissolve into the electrolyte and flow to the cathode, texturizing the surface of the interconnect structures (e.g., anode). Depending on the electrolyte bath chemistry, material composition, and electrical conditions, texturizing of the surface of the interconnect structure may be increased or lessened.

In some embodiments, the surface of an interconnect structure may be texturized using a press and anvil structure. The interconnect structure may be pressed, stretched, and/or deformed by the press and anvil structure to texturize the surface of the interconnect structure. In some embodiments, the press and anvil structure may emboss a texturized pattern into the surface of the interconnect structure. In some embodiments, multiple steps may be taken with multiple press and anvil structure devices in an in line progressive setup.

In some embodiments, a bonding device may texturize the surface of an interconnect structure. For instance, a wire bonder head may be used to ultrasonically bond the interconnect structure to other components, but before bonding, the wire bonder head may texturize the surface of the interconnect structure. For example, the wire bonder head may perform an ultrasonic scrubbing process or a bonding process on the interconnect structure to texturize the surface of the interconnect structure. An ultrasonic scrubbing process may apply pressure and/or ultrasonic energy or vibrations to the interconnect structure against a surface to texturize the surface of the interconnect structure.

Aspects of the present disclosure provide a number of technical effects and benefits. For instance, texturizing the surface of interconnect structures may reduce the energy required to complete a bonding process (e.g., ultrasonic wire bonding process) with the interconnect structure. A lower energy requirement during the bonding process may reduce damage to sensitive components, such as the one or more semiconductor die. In addition, the lower energy levels within the bonding process may allow for an increase in the bonding process duration. With a longer bonding process, the bond between the interconnect structure and another component may be more robust and durable. For instance, a bonding process may be restricted to a specific duration so the amount of energy created by the bonding process does not exceed an energy level that may damage sensitive components. Within the restricted duration, only so much of an effective bond may be created. Therefore, by reducing the energy expended in a bonding process, the duration of the bonding process may be increased and remain below the energy level that may damage sensitive components. The longer bonding process may allow for a larger, more robust, bond as a result of the bonding process. In addition, the reduced energy required for bonding may reduce the overall energy required to manufacture semiconductor devices and reduce the overall cost of manufacturing semiconductor devices. Further, more robust and durable bonds within, and between, semiconductor devices and components within semiconductor device packages may reduce the failure rate while manufacturing semiconductor device packages. Reducing the failure rate during manufacturing may reduce the overall cost of semiconductor devices and may reduce the semiconductor materials lost to defective components.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to attaching a semiconductor die to a submount that includes a lead frame in a semiconductor package for purposes of illustration and discussion. Those of ordinary skill in the art, using the disclosures provided herein, will understand that the submount may include other structures, such as a power substrate (e.g., DBC submount. AMB submount, etc.), a clip structure (for clip-attach packages), or other structure. The use of the term “submount” is intended to refer to any structure to which the semiconductor die is attached.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

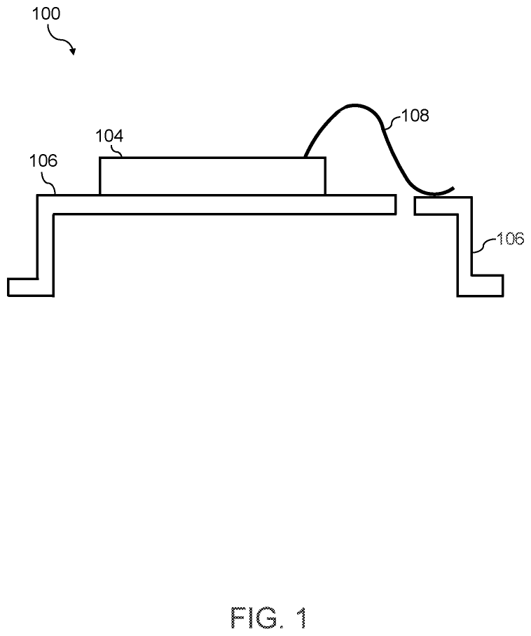

FIG. 1 depicts an example power semiconductor device package 100 according to example embodiments of the present disclosure. The power semiconductor device package 100 may include one or more wide bandgap semiconductor dies 104 (e.g., wide bandgap semiconductor die) mounted on a submount 106. The power semiconductor device package 100 may include an interconnect structure 108 attaching the one or more wide bandgap semiconductor dies 104 to the submount 106. The interconnect structure may be a wire bond structure, ribbon attach structure, or clip attach structure and may electrically couple the one or more semiconductor dies 104 to the submount 106. For example, the one or more semiconductor dies 104 may be mounted to a submount 106, such as a lead frame, and electrically coupled to the submount 106 via at least one of the interconnect structures 108. In some embodiments, the power semiconductor device package 100 may be a power module or a discrete semiconductor package. The semiconductor package 100 may include a housing (not illustrated). The housing may be an insulating material, such as an epoxy mold compound.

The one or more semiconductor dies 104 may include a variety of materials and/or devices. For instance, the one or more semiconductor dies 104 may include silicon carbide. As an example, the one or more semiconductor dies 104 may include a silicon carbide-based MOSFET or Schottky diode. In some embodiments, the one or more semiconductor dies 104 may include a Group III-nitride. As an example, the one or more semiconductor dies 104 may include a Group III nitride-based high electron mobility transistor (e.g., HEMT).

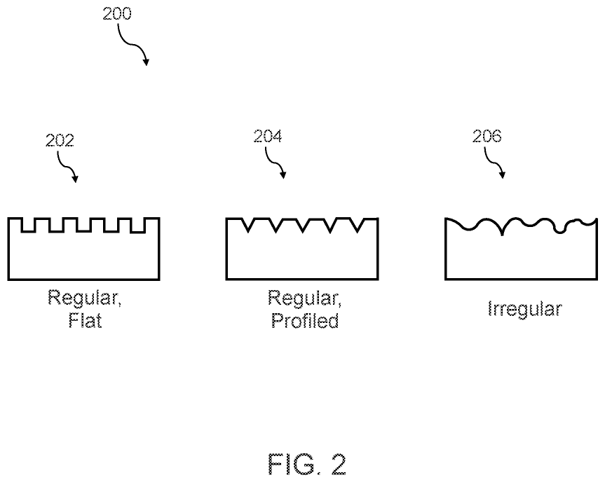

FIG. 2 depicts example texturized surfaces 200 for interconnect structures according to example embodiments of the present disclosure. The example texturized surfaces 200 may be applied to one or more surfaces of an interconnect structure. One example texturized surface may be a regular, flat texturization 202. The regular, flat texturization 202 may include a plurality of grooves following a relatively shallow patterned geometry and/or array with a set depth along a plan along the surface of an interconnect structure. In other words, the regular, flat texturization 202 may include a plurality of grooves with a regular spacing and the plurality of grooves may include perpendicular sidewalls. In some embodiments, the example flat texturization 202 may include a plurality of grooves that extend to a depth in a range of about 5 microns to about 50 for shallow grooves or extend to a depth of about 51 microns to about 100 microns for deeper grooves.

One example texturized surface may be a regular, profiled texturization 204. The regular, profiled texturization 204 may include a plurality of grooves following a relatively shallow patterned geometry and/or array with angled or contoured sidewalls. In some embodiments, the example profiled texturization 204 may include a plurality of grooves that extend to a depth in a range of about 5 microns to about 50 microns for shallow grooves or extend to a depth of about 51 microns to about 100 microns for deeper grooves.

One example texturized surface may be a randomized or irregular roughness 206. The irregular roughness 206 may include a surface roughness Ra in a range between about 5 microns to about 100 microns. The irregular roughness may also include a plurality of grooves with an irregular spacing.

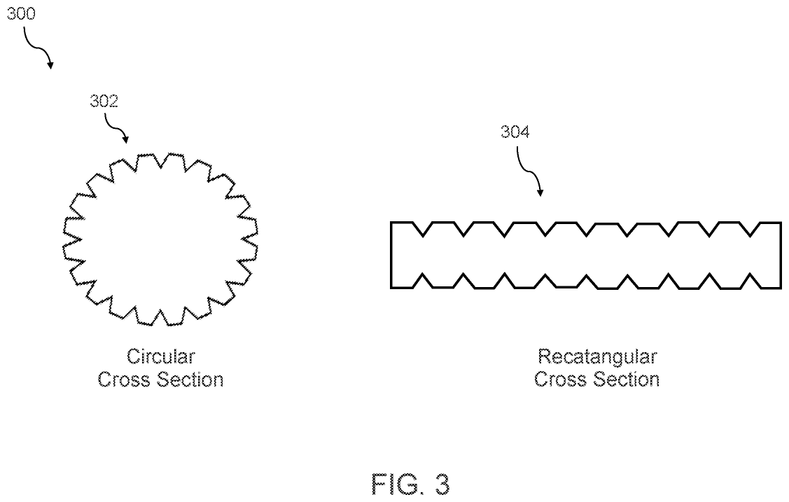

FIG. 3 depicts cross-sectional views of example texturized surfaces 300 according to example embodiments of the present disclosure. In some embodiments, an example texturized surface 302 may be applied to a circular structure, like a wire structure with an annular cross-section. The example texturized surface 302 may be about at least a portion of the surface of the interconnect structure with an annular cross-section. The example texturized surface 302 may be any suitable pattern described herein. In some embodiments, an example texturized surface 304 may be applied to an interconnect structure with polygonal cross-section, like a ribbon structure. The example texturized surface 304 may be applied to at least one polygonal surface about the polygonal cross-section of the interconnect structure.

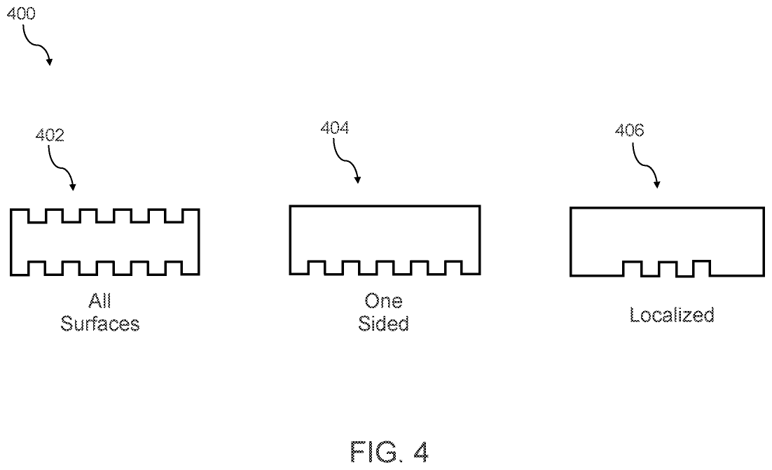

FIG. 4 depicts cross-sectional views of example texturized surfaces 400 according to example embodiments of the present disclosure. In some embodiments, the interconnect structure may have two opposing texturized surfaces, as depicted with respect to interconnect structure 402. In some embodiments, an interconnect structure may have a texturized surface on only one side, as depicted with respect to interconnect structure 404. In some embodiments, an interconnect structure may have a texturized surface in a localized area, as depicted with respect to interconnect structure 406. In some embodiments, an interconnect structure (e.g., a wire bond structure) may only be texturized on its end (e.g., tip).

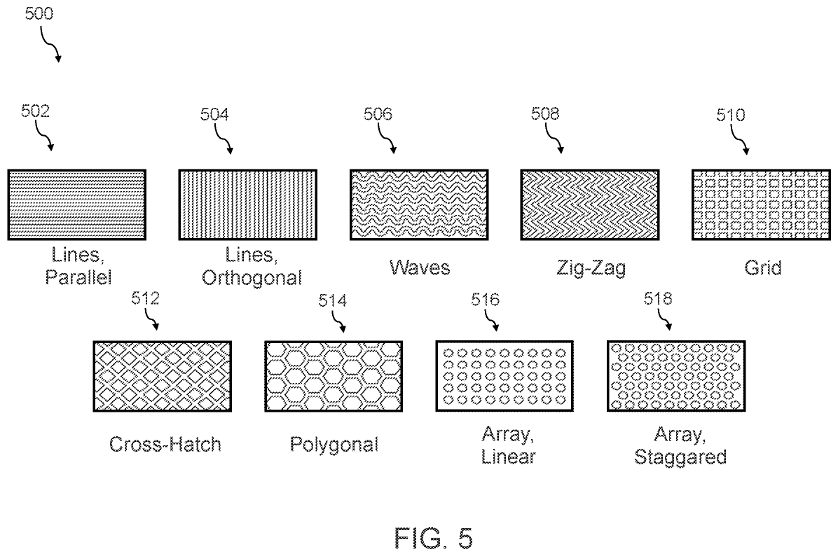

FIG. 5 depicts example texturized patterns 500 according to example embodiments of the present disclosure. The example texturized patterns 500 may include a parallel lines pattern 502, orthogonal lines pattern 504, wave line pattern 506, zig-zag line pattern 508, grid line pattern 510, crosshatch line pattern 512, polygonal line pattern 514, linear array of polygons pattern 516, and a staggered array of polygons pattern 518. The example texturized patterns 500 may be applied to an interconnect structure and may create a texturized surface on the interconnect structure. In some embodiments, the texturized patterns 502-518 may be applied to the surface of an interconnect structure in the manner depicted in FIGS. 2-4. For instance, the example texturized patterns 500 may be applied on opposing surfaces of an interconnect structure as depicted with respect to interconnect structure 402. In some embodiments, the example texturized patterns 500 may be applied on a single surface of an interconnect structure as depicted with respect to interconnect structure 404. In some embodiments, the example texturized patterns 500 may be applied on a localized area of an interconnect structure, as depicted with respect to interconnect structure 406. In some embodiments, the texturized patterns 502-518 may be repeated patterns across at least a portion of the texturized surface of an interconnect structure. It should be appreciated that the patterns 502-518 are for example purposes only. In practice, any texturized pattern or design may be used to texturize the surface of an interconnect structure.

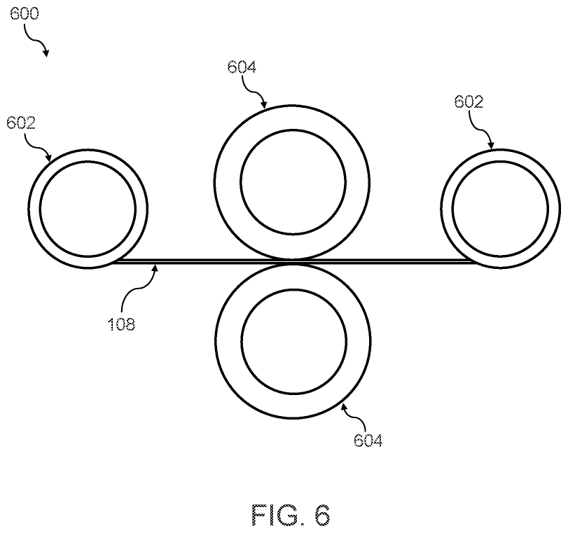

FIG. 6 depicts an example surface texturization process 600 according to example embodiments of the present disclosure. The example surface texturization process 600 may be applied to an interconnect structure 108, such as a wire bond structure, ribbon attach structure, or clip attach structure. The interconnect structure 108 may be stored on reels 602 with the interconnect structure 108 being unwound from one of the reels and rewound onto another of the reels 602 in a reel-to-reel process. Between the reels 602, the interconnect structure 108 may be texturized using one or more rollers 604. The rollers 604 may have a pattern, such as the example texturized patterns 500, on their surface and may apply the pattern to the surface of the interconnect structure 108. In some embodiments, the rollers 604 have a randomized roughness on their surface and may apply a randomized or irregular pattern to the surface of the interconnect structure 108. As depicted, the interconnect structure 108 may be texturized by the rollers 604 on multiple sides and/or surfaces. In some embodiments, the interconnect structure 108 may only be texturized on one side by only one of the rollers 604.

In some embodiments, the one or more rollers 604 may be abrasive wheels. For instance, the one or more rollers 604 may texturize the surface of the interconnect structure 108 in an irregular way, like the irregular roughness 206 depicted in FIG. 2. The one or more rollers 604 may give the surface of the interconnect structure 108 a surface roughness Ra in a range about 5 microns to about 100 microns.

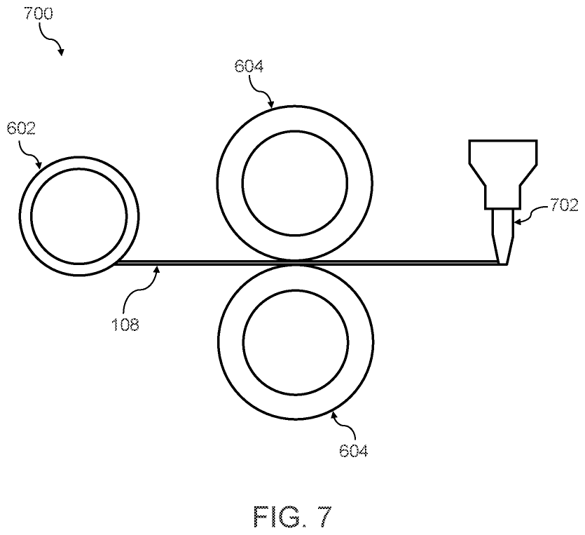

FIG. 7 depicts an example surface texturization process 700 according to example embodiments of the present disclosure. Similar to the process 600 depicted in FIG. 6, the process 700 may utilize one or more reels 602 of an interconnect structure 108 and may texturize the surface of the interconnect structure 108 using the one or more rollers 604. The surface texturization process 700 may be performed in line with a bonding process using the bonding head 702. The bonding head 702 may be operable, for instance, to ultrasonically bond the interconnect structure 108 to a component of a semiconductor device package (e.g., semiconductor die or submount (lead frame)). For instance, the interconnect structure 108 may be texturized by the one or more rollers 604 and then attached to a semiconductor die using the bonding head 702 as part of a bonding process.

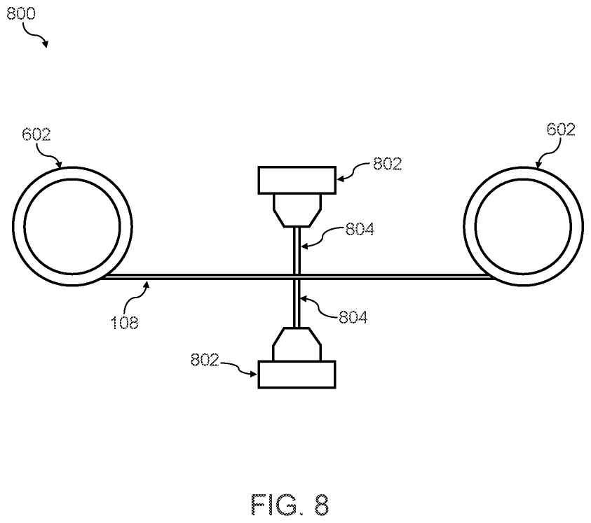

FIG. 8 depicts an example surface texturization process 800 according to example embodiments of the present disclosure. The example surface texturization process 800 may be a reel-to-reel process similar to the example surface texturization process 600. However, the process 800 may include one or more laser ablation systems 802. The laser ablation systems 802 may emit lasers 804 that may texturize the surface of the interconnect structure 108. For instance, the lasers804 may ablate one of the example texturized patterns 500, depicted in FIG. 5, into the surface of the interconnect structure 108. In some embodiments, there may multiple lasers804 that texturize multiple sides and/or surfaces of the interconnect structure 108. In some embodiments, there may be one laser beam 804 that texturizes one side and/or surface of the interconnect structure 108.

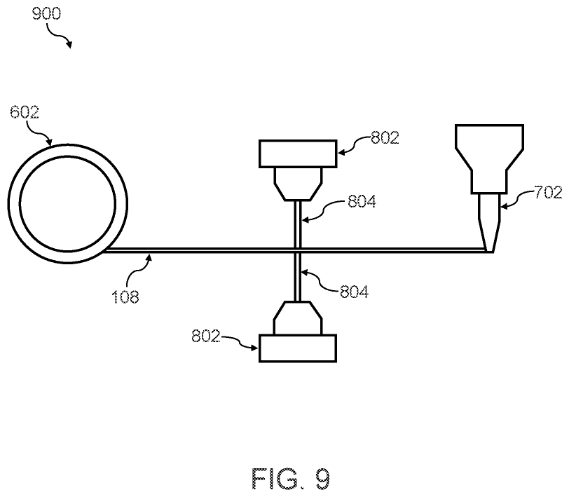

FIG. 9 depicts an example surface texturization process 900 according to example embodiments of the present disclosure. The example surface texturization process 900 may be similar to the process 800 depicted in FIG. 8. However, the process 900 may perform the texturization of the surface of the interconnect structure 108 in line with a bonding process performed by the bonding head 702. The bonding head 702 may be operable, for instance, to ultrasonically bond the interconnect structure 108 to a component of a semiconductor device package (e.g., semiconductor die or submount (lead frame)). For instance, the interconnect structure 108 may be texturized by the lasers804 before being bonded to a semiconductor die using the bonding head 702 as part of a bonding process.

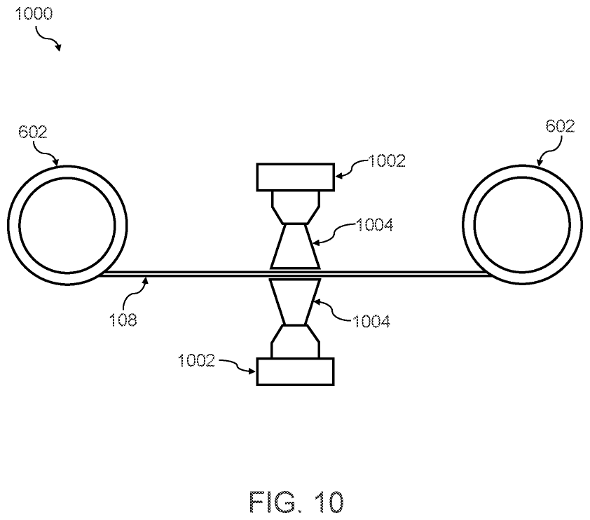

FIG. 10 depicts an example surface texturization process 1000 according to example embodiments of the present disclosure. The example surface texturization process 1000 may be a reel-to-reel process similar to the process 600 depicted in FIG. 6. However, the surface of the interconnect structure may be texturized using one or more spraying nozzles 1002. The one or more spraying nozzles 1002 may emit an abrasive spray 1004 that may texturize the surface of the interconnect structure 108. The abrasive spray may remove material from the surface of the interconnect structure 108 to texturize the surface. In some embodiments, the abrasive spray 1004 may be an etchant spray. The etchant spray may chemically etch material from the surface of the interconnect structure 108 to texturize the surface of the interconnect structure 108. In some embodiments, the one or more spraying nozzles 1002 may texturize the surface of the interconnect structure 108 in line with, and before, a bonding process similar to the process 700 depicted in FIG. 7.

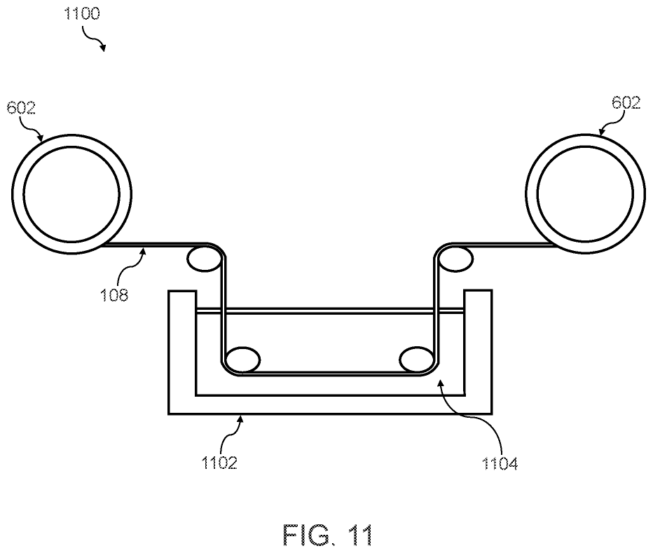

FIG. 11 depicts an example surface texturization process 1100 according to example embodiments of the present disclosure. The example surface texturization process 1100 may be a reel-to-reel process similar to the process 600 depicted in FIG. 6. However, the process 1100 may use an etchant liquid 1104 in a bath 1102 to texturize the surface of the interconnect structure 108. The interconnect structure 108 may be pushed through the bath 1102 and the etchant liquid 1104 may remove or etch material from the surface of the interconnect structure 108 to texturize the surface of the interconnect structure 108.

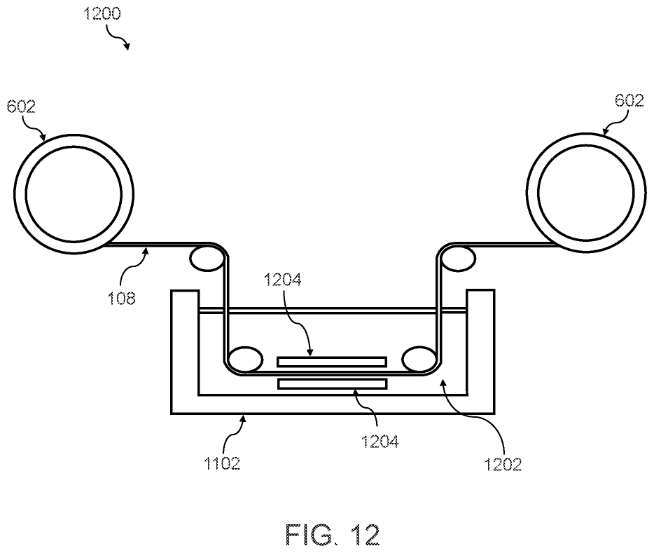

FIG. 12 depicts an example surface texturization process 1200 according to example embodiments of the present disclosure. The example surface texturization process 1200 may be a reel-to-reel process similar to the process 1100 depicted in FIG. 11. The interconnect structure 108 may be passed through a bath 1102 to texturize the surface of the interconnect structure 108. However, the bath 1102 may hold an electrolyte liquid 1202 and may cause the interconnect structure 108 to undergo an electrolysis process. For instance, the interconnect structure 108 may have a current applied to it and may become an anode within the electrolyte liquid 1202. The interconnect structure 108 may be moved through one or more cathode plates 1204 within the electrolyte liquid 1202 to etch and texturize the surface of the interconnect structure 108 (e.g., an electrolysis process). For instance, the atoms within the anode (e.g., interconnect structure 108) may move to the cathode plates 1204 within the electrolyte liquid 1202 to texturize the surface of the anode. In some embodiments, the amount of texturization to the surface of the interconnect structure 108 may be adjusted by the chemistry of the electrolyte liquid 1202 and the material composition and electrical state of the interconnect structure 108.

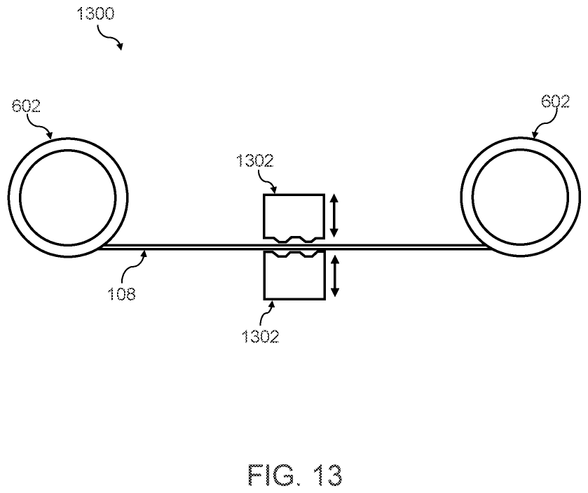

FIG. 13 depicts an example surface texturization process 1300 according to example embodiments of the present disclosure. The example surface texturization process 1300 may be a reel-to-reel process similar to the process 600 depicted in FIG. 6. However, the process 1300 may include a press and anvil structure 1302 that texturizes the surface of the interconnect structure 108. In some embodiments, the press and anvil structure 1302 may stretch, press, and deform the interconnect structure 108 to texturize the surface of the interconnect structure 108. For instance, the press and anvil structure 1302 may emboss a texturized pattern, such as the example texturized patterns 500 depicted in FIG. 5, into one or more surfaces of the interconnect structure 108.

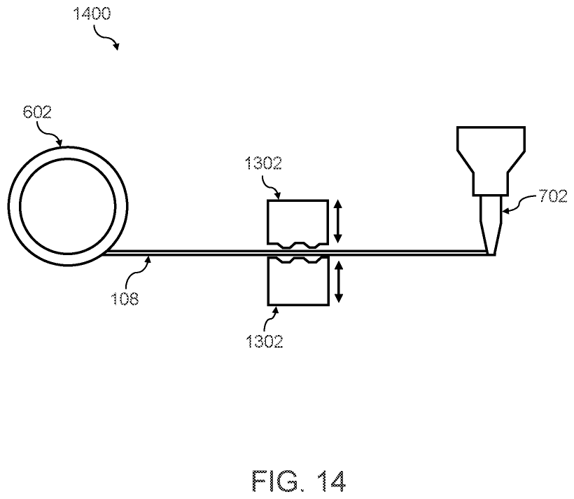

FIG. 14 depicts an example surface texturization process 1400 according to example embodiments of the present disclosure. The example surface texturization process 1400 may be similar to the process 1300 depicted in FIG. 13. However, the process 1400 may be performed in line with a bonding process. For instance, the press and anvil structure 1302 may texturize the surface of the interconnect structure 108 before the bonding head 702 performs a bonding process with the interconnect structure 108. The bonding head 702 may be operable, for instance, to ultrasonically bond the interconnect structure 108 to a component of a semiconductor device package (e.g., semiconductor die or submount (lead frame)). For example, the press and anvil structure 1302 may texturize the surface of the interconnect structure 108 and then the bonding head 702 may ultrasonically bond the interconnect structure 108 to, for example, a semiconductor die.

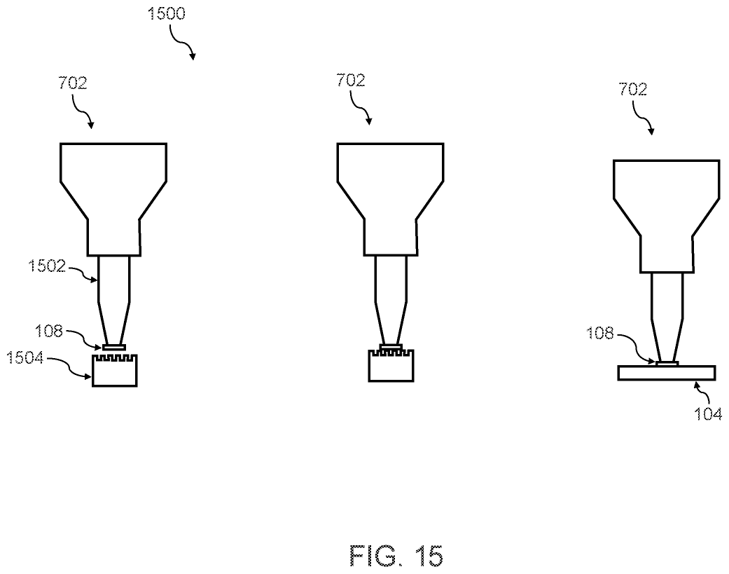

FIG. 15 depicts an example surface texturization process 1500 according to example embodiments of the present disclosure. The example surface texturization process 1500 may utilize the bonding head 702 to texturize the surface of the interconnect structure 108. In some embodiments, the bonding head 702 may be an ultrasonic device and may first engage the interconnect structure 108 with a texturizing tool 1504 and ultrasonically vibrate the interconnect structure 108 against the texturizing tool 1504 to texturize the surface of the interconnect structure 108. In some embodiments, the bonding head 702 may apply pressure and/or ultrasonic energy to scrub the interconnect structure 108 against the texturizing tool 1504. In some embodiments, the bonding head 702 may texturize one or more surfaces of the interconnect structure 108 and then may perform a bonding process using the interconnect structure 108. For instance, the bonding head 702 may texturize the surface of the interconnect structure 108 and then may ultrasonically bond the interconnect structure 108 to, for example, a semiconductor die 104

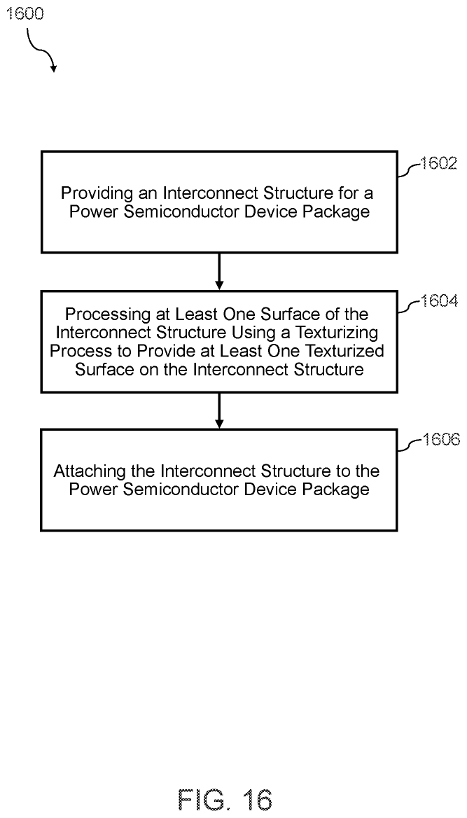

FIG. 16 depicts a block diagram of an example method 1600 for improving adhesion of an interconnect structure according to example embodiments of the present disclosure. FIG. 16 depicts operations performed in a particular order for purposes of illustration and discussion. Those of ordinary skill in the art, using the disclosures provided herein, will understand that various operations of any of the methods described herein can be adapted, expanded, omitted, rearranged, include steps or operations not illustrated, and/or modified in various ways without deviating from the scope of the present disclosure.

At 1602, the method includes providing an interconnect structure for a power semiconductor device package. In some embodiments, the interconnect structure may be a wire bond structure, ribbon attach structure, or clip attach structure. The interconnect structure may be provided using reels of the interconnect structure. The interconnect structure may be unwound from one reel to be provided for the power semiconductor device package.

At 1604, the method includes processing at least one surface of the interconnect structure using a texturizing process to provide at least one texturized surface on the interconnect structure.

In some embodiments, the texturizing process may be performed through mechanical methods and/or processes. For instance, the texturizing process may be performed in a reel-to-reel rolling process. The texturizing process may mechanically roughen at least one surface of the interconnect structure. In some embodiments, the texturizing process may mechanically emboss at least one surface of the interconnect structure. In some embodiments, at least one surface of the interconnect structure may be mechanically embossed using a press and anvil structure.

In some embodiments, the texturizing process may be performed through chemical methods and/or processes. For instance, the texturizing process may include a chemical etching process. In some embodiments, the chemical etching process may be performed by, at least partially, providing the interconnect structure in an etchant bath. In some embodiments, the chemical etching process may be performed by applying an etchant spray to the interconnect structure.

In some embodiments, the texturizing process may include an electrolysis process. The electrolysis process may be performed by providing the interconnect structure in an electrolyte bath and moving the interconnect structure between cathode plates.

In some embodiments, the texturizing process may include a laser etching process. One or more lasers may etch the surface of the interconnect structure to texturize the surface of the interconnect structure.

In some embodiments, the texturizing process may include an ultrasonic roughening process. For instance, an ultrasonic device used for attaching the interconnect structure to a power semiconductor device package may perform the ultrasonic roughening process. In some embodiments the ultrasonic device may ultrasonically vibrate the interconnect structure against a texturizing device to, at least partially, texturize the surface of the interconnect structure.

At 1606, the method includes attaching the interconnect structure to the power semiconductor package. In some embodiments, the texturizing process of 1604 may be performed in line with the attaching of the interconnect structure to the power semiconductor device package. In some embodiments, the power semiconductor package may be a power module or a discrete semiconductor package.

In some embodiments, the power semiconductor device package may include different materials and/or devices. For instance, the power semiconductor device package may include silicon carbide. As an example, the power semiconductor device package may include a silicon carbide-based MOSFET or Schottky diode. In some embodiments, the power semiconductor device package may include one or more wide bandgap semiconductor die including a Group III-nitride. As an example, the power semiconductor device package may include a Group III nitride-based high electron mobility transistor.

Example aspects of the present disclosure are set forth below. Any of the below features or examples may be used in combination with any of the embodiments or features provided in the present disclosure.

One example aspect of the present disclosure is directed to a power semiconductor device package. The power semiconductor device package includes one or more semiconductor die. The power semiconductor device package includes a submount. The one or more semiconductor die are on the submount. The power semiconductor device package includes at least one interconnect structure. The at least one interconnect structure includes at least one texturized surface.

In some examples, the at least one texturized surface has a surface roughness Ra in a range of about 5 microns to about 100 microns.

In some examples, the interconnect structure is a wire bond structure, a ribbon attach structure, or a clip attach structure.

In some examples, the interconnect structure has an annular cross-section, wherein the at least one texturized surface comprises at least a portion of a surface about the annular cross-section.

In some examples, the interconnect structure has a polygonal cross-section, wherein the at least one texturized surface comprises at least one polygonal surface about the polygonal cross-section.

In some examples, the at least one texturized surface comprises a plurality of grooves on the at least one texturized surface.

In some examples, the plurality of grooves have a regular spacing.

In some examples, the plurality of grooves have an irregular spacing.

In some examples, at least one of the plurality of grooves extends to a depth of about

5 microns to about 50 microns.

In some examples, at least one of the plurality of grooves extends to a depth of about

51 microns to about 100 microns.

In some examples, the plurality of grooves has generally perpendicular sidewalls.

In some examples, the plurality of grooves has angled sidewalls.

In some examples, the at least one texturized surface comprises a texturized pattern.

In some examples, the texturized pattern is a repeated pattern across at least a portion of the texturized surface.

In some examples, the texturized pattern is a parallel line pattern. In some examples, the texturized pattern is an orthogonal line pattern. In some examples, the texturized pattern is a wave line pattern. In some examples, the texturized pattern is a zig-zag line pattern. In some examples, the texturized pattern is a grid line pattern. In some examples, the texturized pattern is a crosshatch line pattern. In some examples, the texturized pattern is a polygonal line pattern. In some examples, the texturized pattern is a linear array of polygons. In some examples, the texturized pattern is a staggered array of polygons.

In some examples, the at least one texturized surface comprises a localized area of a surface of the interconnect structure. In some examples, the interconnect structure comprises a plurality of texturized surfaces.

In some examples, the submount is a lead frame, wherein the lead frame comprises a texturized surface.

In some examples, the one or more semiconductor die comprise silicon carbide.

In some examples, the power semiconductor device package comprises a silicon carbide-based MOSFET or Schottky diode.

In some examples, the one or more semiconductor die comprise a Group III-nitride.

In some examples, the power semiconductor device package comprises a Group III nitride-based high electron mobility transistor.

In some examples, the power semiconductor device package is a power module.

In some examples, the power semiconductor device package is a discrete semiconductor package.

Another example aspect of the present disclosure is directed to a method. The method includes providing an interconnect structure for a power semiconductor device package. The method includes processing at least one surface of the interconnect structure using a texturizing process to provide at least one texturized surface on the interconnect structure.

In some examples, the method includes attaching the interconnect structure to the power semiconductor device package.

In some examples, the texturizing process is performed in line with the attaching of the interconnect structure to the power semiconductor device package.

In some examples, the texturizing process comprises a reel-to-reel rolling process.

In some examples, the texturizing process mechanically roughens at least one surface of the interconnect structure.

In some examples, the texturizing process mechanically embosses at least one surface of the interconnect structure.

In some examples, the texturizing process mechanically embosses at least one surface of the interconnect structure using a press and an anvil structure.

In some examples, the texturizing process comprises a chemical etching process.

In some examples, the chemical etching process is performed by at least partially providing the interconnect structure in an etchant bath.

In some examples, the chemical etching process is performed by applying an etchant spray to the interconnect structure.

In some examples, the texturizing process comprises an electrolysis process.

In some examples, the electrolysis process is performed by providing the interconnect structure in an electrolyte bath and moving the interconnect structure between cathode plates.

In some examples, the texturizing process comprises a laser etching process.

In some examples, the texturizing process comprises an ultrasonic roughening process.

In some examples, the ultrasonic roughening process is performed by an ultrasonic device used for attaching the interconnect structure to the power semiconductor device package.

In some examples, the power semiconductor device package comprises one or more wide bandgap semiconductor die comprising silicon carbide.

In some examples, the power semiconductor device package comprises a silicon carbide-based MOSFET or Schottky diode.

In some examples, the power semiconductor device package comprises one or more wide bandgap semiconductor die comprising a Group III-nitride.

In some examples, the power semiconductor device package comprises a Group III nitride-based high electron mobility transistor.

In some examples, the power semiconductor device package is a power module.

In some examples, the power semiconductor device package is a discrete semiconductor package.

Another example aspect of the present disclosure is directed to an interconnect structure for a power semiconductor device package. The interconnect structure includes a conductive structure. The interconnect structure includes at least one texturized surface on the conductive structure.

In some examples, the interconnect structure is a wire bond structure, a ribbon attach structure, or a clip attach structure.

In some examples, the interconnect structure has an annular cross-section, wherein the at least one texturized surface comprises at least a portion of a surface about the annular cross-section.

In some examples, the interconnect structure has a polygonal cross-section, the at least one texturized surface comprises at least one polygonal surface about the polygonal cross-section.

In some examples, the at least one texturized surface comprises a plurality of grooves on the at least one texturized surface.

In some examples, the plurality of grooves has a regular spacing.

In some examples, the plurality of grooves has an irregular spacing.

In some examples, at least one of the plurality of grooves extend to a depth of about 5microns to about 50 microns.

In some examples, at least one of the plurality of grooves extend to a depth of about 51 microns to about 100 microns.

In some examples, the plurality of grooves has generally perpendicular sidewalls.

In some examples, the plurality of grooves has angled sidewalls.

In some examples, the at least one texturized surface comprises a texturized pattern.

In some examples, the texturized pattern comprises a repeated pattern across at least a portion of the at least one texturized surface.

In some examples, the texturized pattern is a parallel line pattern. In some examples, the texturized pattern is an orthogonal line pattern. In some examples, the texturized pattern is a wave line pattern. In some examples, the texturized pattern is a zig-zag line pattern. In some examples, the texturized pattern is a grid line pattern. In some examples, the texturized pattern is a crosshatch line pattern. In some examples, the texturized pattern is a polygonal line pattern. In some examples, the texturized pattern is a linear array of polygons. In some examples, the texturized pattern is a staggered array of polygons.

In some examples, the at least one texturized surface comprises a localized area of a surface of the interconnect structure.

In some examples, the interconnect structure comprises a plurality of texturized surfaces.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor device package, comprising:
one or more semiconductor die;
a submount, wherein the one or more semiconductor die are on the submount; and
at least one interconnect structure, the at least one interconnect structure comprising at least one texturized surface.

2. The power semiconductor device package of claim 1, wherein the at least one texturized surface has a surface roughness Ra in a range of about 5 microns to about 100 microns.

3. The power semiconductor device package of claim 1, wherein the interconnect structure is a wire bond structure, a ribbon attach structure, or a clip attach structure.

4. The power semiconductor device package of claim 1, wherein the interconnect structure has an annular cross-section, wherein the at least one texturized surface comprises at least a portion of a surface about the annular cross-section.

5. The power semiconductor device package of claim 1, wherein the interconnect structure has a polygonal cross-section, wherein the at least one texturized surface comprises at least one polygonal surface about the polygonal cross-section.

6. The power semiconductor device package of claim 1, wherein the at least one texturized surface comprises a plurality of grooves on the at least one texturized surface.

7. The power semiconductor device package of claim 6, wherein the plurality of grooves have a regular spacing or an irregular spacing.

8. (canceled)

9. The power semiconductor device package of claim 6, wherein at least one of the plurality of grooves extends to a depth of about 5 microns to about 50 microns.

10. The power semiconductor device package of claim 6, wherein at least one of the plurality of grooves extends to a depth of about 51 microns to about 100 microns.

11. The power semiconductor device package of claim 6, wherein the plurality of grooves has generally perpendicular sidewalls or angled sidewalls.

12. (canceled)

13. The power semiconductor device package of claim 6, wherein the at least one texturized surface comprises a texturized pattern, wherein the texturized pattern is a repeated pattern across at least a portion of the texturized surface.

14. (canceled)

15. The power semiconductor device package of claim 13, wherein the texturized pattern is a parallel line pattern, an orthogonal line pattern, a wave line pattern, a zig-zag line pattern, a grid line pattern, a crosshatch line pattern, a polygonal line pattern, a linear array of polygons, or a staggered array of polygons

16-23. (canceled)

24. The power semiconductor device package of claim 1, wherein the at least one texturized surface comprises a localized area of a surface of the interconnect structure.

25. The power semiconductor device package of claim 1, wherein the interconnect structure comprises a plurality of texturized surfaces.

26. The power semiconductor device package of claim 1, wherein the submount is a lead frame, wherein the lead frame comprises a texturized surface.

27. The power semiconductor device package of claim 1, wherein the one or more semiconductor die comprise silicon carbide.

28. (canceled)

29. The power semiconductor device package of claim 1, wherein the one or more semiconductor die comprise a Group III-nitride.

30. (canceled)

31. The power semiconductor device package of claim 1, wherein the power semiconductor device package is a power module or a discrete semiconductor package.

32. (canceled)

33. A method, comprising:
providing an interconnect structure for a power semiconductor device package; and
processing at least one surface of the interconnect structure using a texturizing process to provide at least one texturized surface on the interconnect structure.

34-53. (canceled)

54. An interconnect structure for a power semiconductor device package, comprising:
a conductive structure; and
at least one texturized surface on the conductive structure.

55-77. (canceled)
